(19) United States
(12) Patent Application Publication
(10) Pub. No.: US 2024/0110987 A1
(43) Pub. Date: Apr. 4, 2024

(54) BATTERY DETECTION METHOD AND BATTERY DETECTION DEVICE

(71) Applicant: Lenovo (Beijing) Limited, Beijing (CN)

(72) Inventors: Zhuoqun TANG, Beijing (CN); Hui KONG, Beijing (CN); Zhilong TANG, Beijing (CN)

(21) Appl. No.: 18/461,107

(22) Filed: Sep. 5, 2023

(30) Foreign Application Priority Data
Sep. 26, 2022 (CN) 202211174899.X

(51) Int. Cl. G01R 31/3835; G01R 31/367; G01R 31/389; H02J 7/00

(52) U.S. Cl. CPC G01R 31/3835; G01R 31/367; G01R 31/389; H02J 7/0047; H02J 7/00712

(57) ABSTRACT

A battery detection method includes determining a first loading parameter of a first pulse current; loading the first pulse current on a battery under test based on the first loading parameter to obtain a first changing rate of voltage of the battery under test; and determining whether an internal short circuit occurs in the battery under test based on the first changing rate.

### CROSS-REFERENCE TO RELATED APPLICATION

This application claims priority to Chinese Patent Application No. 202211174899.X, filed on Sep. 26, 2022, the content of which is incorporated herein by reference in its entirety.

### TECHNICAL FIELD

The present disclosure generally relates to the field of battery technologies and, more particularly, to a battery detection method and a battery detection device.

### BACKGROUND

Macroscopically, an internal short circuit (ISC) of a battery can be divided into a soft short circuit and a hard short circuit. In the soft short circuit (SSC), the transport of lithium ions and electrons is present in the battery at the same time, usually because the battery is over-charged or over-discharged. Battery failure caused by the soft short circuit will not bring catastrophic consequences, but the performance characteristics are extremely inconspicuous. In the hard short circuit (HSC), only transport of the electrons exists in the battery, usually due to external puncture. The hard short circuit has a higher short-circuit current density. When the hard short circuit occurs, the local temperature of the battery rises faster, which is very likely to cause catastrophic consequences such as thermal runaway. The hard short circuit characteristics are easy to detect.

For a customer who uses a portable device, collisions, drops, or extrusions occur from time to time in using scenarios, which will cause the internal short circuit in the battery at the structural level. However, this internal soft short circuit will not immediately cause thermal runaway which may be triggered only under the accumulated conditions. In particular, the portable device has a long service life, and repeated over-charging and over-discharging will also cause the soft short circuit inside the battery, increasing safety risks. The possibility of the soft short circuit occurring is very common in portable devices, but the soft short circuit is difficult to detect and poses a safety hazard to users.

### SUMMARY

In accordance with the present disclosure, there is provided a battery detection method. The battery detection method includes determining a first loading parameter of a first pulse current; loading the first pulse current on a battery under test based on the first loading parameter to obtain a first changing rate of voltage of the battery under test; and determining whether an internal short circuit occurs in the battery under test based on the first changing rate.

In accordance with the present disclosure, there is also provided an electronic device. The electronic device includes one or more processors; and a memory coupled to the one or more processors and storing computer program instructions that, when being executed, cause the one or more processors to perform: determining a first loading parameter of a first pulse current; loading the first pulse current on a battery under test based on the first loading parameter to obtain a first changing rate of voltage of the battery under test; and determining whether an internal short circuit occurs in the battery under test based on the first changing rate.

In accordance with the present disclosure, there is also provided a non-transitory computer readable storage medium containing computer program instructions that, when being executed, cause one or more processors to perform: determining a first loading parameter of a first pulse current; loading the first pulse current on a battery under test based on the first loading parameter to obtain a first changing rate of voltage of the battery under test; and determining whether an internal short circuit occurs in the battery under test based on the first changing rate.

As disclosed, by loading the first pulse current with the first loading parameter on the battery under test, the first changing rate of the voltage of the battery under test may be obtained. Therefore, whether the internal short circuit occurs in the battery under test may be detected when the response to the leakage charge is amplified and the changing rate of the voltage varies. It may be more timely, efficiently, accurately, concisely and intuitively to determine whether the internal short circuit occurs in the battery under test.

### BRIEF DESCRIPTION OF THE DRAWINGS

The following drawings are merely examples for illustrative purposes according to various disclosed embodiments and are not intended to limit the scope of the present disclosure. In the drawings, same or similar reference numerals/characters refer to the same or corresponding parts.

FIG. 1 is a flow chart of a battery detection method consistent with some embodiments of the present disclosure.

FIG. 2 is a schematic diagram of a relationship between a battery voltage and a short-circuit resistance consistent with some embodiments of the present disclosure.

FIG. 3 is a schematic diagram of an equivalent circuit of a charging state consistent with some embodiments of the present disclosure.

FIG. 4 is a schematic diagram of an equivalent circuit of a discharging state consistent with some embodiments of the present disclosure.

FIG. 5 is a schematic diagram of a discharging curve of a battery consistent with some embodiments of the present disclosure.

FIG. 6 is a schematic diagram of another discharging curve of a battery consistent with some embodiments of the present disclosure.

FIG. 7 is a detection logic flow of a battery under test consistent with some embodiments of the present disclosure.

FIG. 8 is a structural diagram of a battery detection device consistent with some embodiments of the present disclosure.

FIG. 9 is a structural diagram of an electronic device consistent with some embodiments of the present disclosure.

### DETAILED DESCRIPTION OF THE EMBODIMENTS

Hereinafter, embodiments and features consistent with some embodiments of the present disclosure will be described with reference to drawings. Various modifications may be made to the embodiments of the present disclosure. Thus, the described embodiments should not be regarded as limiting, but are merely examples. Those skilled in the art will envision other modifications within the scope and spirit of the present disclosure.

The accompanying drawings, which are incorporated in and constitute a part of this specification, illustrate embodiments of the present disclosure and, together with the general description of the present disclosure above and the detailed description of the embodiments below, serve to explain the principle of the present disclosure.

These and other features of the present disclosure will become apparent from the following description of non-limiting embodiments with reference to the accompanying drawings.

Although the present disclosure is described with reference to some specific examples, those skilled in the art will be able to realize many other equivalents of the present disclosure.

The above and other aspects, features, and advantages of the present disclosure will become more apparent in view of the following detailed description when taken in conjunction with the accompanying drawings.

Specific embodiments of the present disclosure are hereinafter described with reference to the accompanying drawings. The described embodiments are merely examples of the present disclosure, which may be implemented in various ways. Specific structural and functional details described herein are not intended to limit, but merely serve as a basis for the claims and a representative basis for teaching one skilled in the art to variously employ the present disclosure in substantially any suitable detailed structure.

As disclosed, the phrases such as “in one embodiment”, “in another embodiment”, “in yet another embodiment”, or “in other embodiments”, may all refer to one or more of different embodiments in accordance with the present disclosure.

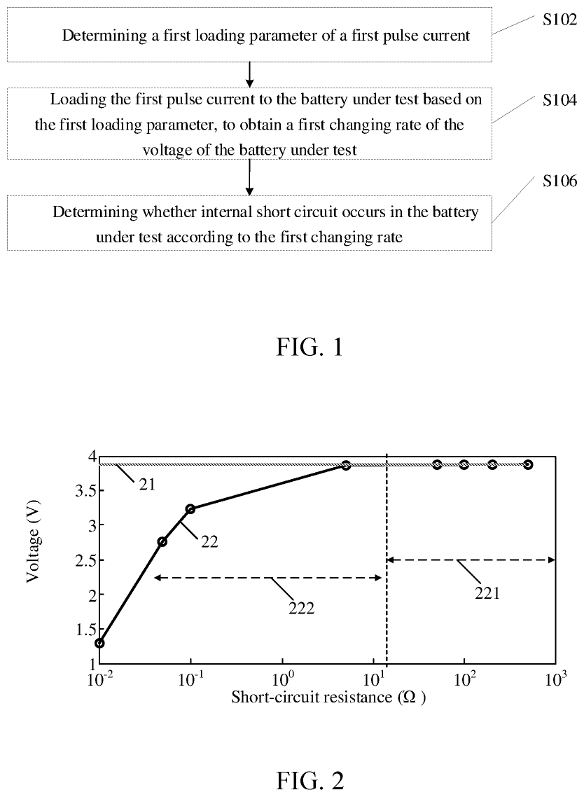

The present disclosure provides a battery detection method. In one embodiment, as shown in FIG. 1 illustrating a flow chart of the battery detection method provided by the present embodiment, the method may include S102 to S106.

In S102, a first loading parameter of a first pulse current may be determined.

In one embodiment, the first loading parameter may include a current intensity of the first pulse current to be loaded, current loading time, a current loading frequency, or cut-off voltage of a battery under test. The current intensity may be expressed as I, which may be 0.1 C (where C is the charge or discharge rate), 0.3 C, 0.5 C, 1 C, 2 C, etc. The current loading time may be expressed as t, which may be 1 second, 10 seconds, 1 minute, etc. The current loading frequency may be expressed as f The cut-off voltage may be expressed as U. The cut-off voltage during charging may be 4.2 V, 4.3 V, 4.4V, etc. The cut-off voltage during discharge may be 3.4V, 3.2V, 3.0V, etc.

In S104, the first pulse current may be loaded on the battery under test based on the first loading parameter, to obtain a first changing rate of the voltage of the battery under test.

The first pulse current may be loaded on the battery under test to perform pulse charging or pulse discharging on the battery to be tested. Subsequently, the changing rate of the voltage of the battery under test during charging or discharging may be obtained.

In S106, based on the first changing rate, whether an internal short circuit occurs in the battery under test may be determined.

In a typical commercial mobile battery, the short circuit resistance of a normal battery is regarded as infinite, and the short circuit resistance of a failed battery is about 3Ω to 20Ω. It can be understood that any short circuit with a resistance higher than a certain threshold may be considered a soft short circuit, and any short circuit with a resistance below this threshold is considered a hard short circuit. As shown in FIG. 2, 21 is the voltage curve of the normal battery, 22 is the voltage curve of the short-circuit battery, 221 is the soft short circuit stage of the short-circuited battery, and 222 is the hard short circuit stage of the short circuit battery. The short circuit resistance of the short circuit battery is very large during the soft short circuit, such that the voltage of the soft short circuit battery is not much different from the voltage of the healthy battery and it is difficult to detect whether a soft short circuit occurs by only the voltage. The voltage drop is obvious in the case of a hard short circuit which can be judged from any one of the short circuit resistance, voltage or temperature. However, there is already a risk of thermal runaway now, and it is too late to warn.

Therefore, early detection of an internal short circuit in the battery may be used to warn the user and avoid catastrophic events.

Because a battery with an internal short circuit may generate leakage current and the leakage current may occupy the charging/discharging capacity of the battery. Therefore, the changing rate of the battery voltage may change. Also, the pulse current may have the effect of amplifying the leakage charge response. Therefore, by loading the battery under test with a pulse current, whether the internal short circuit occurs in the battery under test may be detected according to the changing rate of the voltage of the battery under test with the pulse current.

As disclosed, by loading the first pulse current with the first loading parameter on the battery under test, the first changing rate of the voltage of the battery under test may be obtained. Therefore, whether the internal short circuit occurs in the battery under test may be detected when the response to the leakage charge is amplified and the changing rate of the voltage varies. It may be more timely, efficient, accurate, concise and intuitive to determine whether the internal short circuit occurs in the battery under test.

In some embodiments, the method may further include:

S1011: determining a first scenario where the battery under test is located; and

S1012: determining the first loading parameters of the first pulse current according to the first scenario.

The first scenario may be associated with at least one of the state of charge of the battery under test, the charging/discharging rate of the battery under test, or the temperature of the battery under test.

The state of charge may be expressed as SOC (State of Charge), which is used to reflect the ratio of the remaining capacity of the battery under test to the capacity of the fully charged state of the battery under test. The charging/discharging rate of the battery under test may be numerically equal to the multiple of the rated capacity of the battery under test, and may be expressed as C. The charging/discharging rate=the charging/discharging current/the rated capacity. The temperature may be expressed as T. Combinations of different states of charge, different charging/discharging rates, and different temperatures may form different first scenarios. In some embodiments, the first scenarios may also be related to the aging degree of the battery under test. The first loading parameters of the first pulse current loaded for the battery under test in different first scenarios may be different. For each first scenario, a certain type of battery may be loaded with pulse currents with different first loading parameters for multiple times until a pulse current with a loading parameter that is able to amplify the leakage charge effect to the limit without causing current overload is found, and the loading parameter may be determined as the first loading parameter of the first pulse current of the battery of this type in the first scenario.

As disclosed, by determining the first scenario of the battery under test, the first loading parameter of the first pulse current may be determined and the changing rate of the voltage of the battery under test corresponding to the first loading parameter in the first scenario may be obtained. By associating the first scenario and the first loading parameter with the first changing rate, suitable loading parameters may be more accurately determined for different scenarios, such that the changing rate of the voltage under different loading parameters may be more accurately determined.

In one embodiment, determining the first loading parameters of the first pulse current according to the first scenario in S1012 may include:
determining the current intensity and the current loading time of the first pulse current, or the current intensity and the cut-off voltage of the battery under test, according to the first scenario.

Correspondingly, loading the first pulse current on the battery under test based on the first loading parameter to obtain the first changing rate of the voltage of the battery under test in S104 may include S1041 or S1042.

In S1041, the first changing rate of the voltage of the battery under test may be obtained based on the current intensity and the current loading time.

The current loading time may be specified as t. Within the range of the current loading time, it may be determined that the voltage variation of the battery under test is ΔV with the current intensity. Based on the ratio of the voltage variation and the current loading time, the first changing rate k of the voltage of the battery under test may be obtained as k=ΔV/t.

In S1042: the first changing rate of the voltage of the battery under test may be obtained based on the current intensity and the cut-off voltage of the battery under test.

The cut-off voltage V₁ may also be specified, and the duration Δt of the battery under test from the initial voltage V₀ to the cut-off voltage V₁ may be determined under the current intensity. Based on the variation from the initial voltage to the cut-off voltage V₁ and the duration Δt, the first changing rate k of the voltage of the battery under test may be obtained as k=(V₁−V₀)/Δt.

It can be seen that both S1041 and S1042 may be able to determine the slope of the voltage-time curve of the battery under test.

As disclosed, the changing rate of the voltage may be determined through the current intensity and the current loading time, or the changing rate of the voltage may be determined the current intensity and the cut-off voltage of the battery under test, improving the flexibility and variety of the determination of the changing rate of the voltage.

In one embodiment, determining whether the internal short circuit occurs in the battery under test based on the first changing rate in S106 may include:

S1061: determining a target scenario corresponding to the first scenario; and

S1062: comparing the first changing rate to a first target changing rate corresponding to the target scenario to determine whether the internal short circuit occurs in the battery under test.

The target scenario may be a preset scenario in a standard database.

The target scenario may be a preset scenario consistent (that is, the same as or with a high degree of similarity to) with the first scenario among the preset scenarios of the standard database. The first target changing rate may be a changing rate of the voltage of a normal battery without an internal short circuit. Since the leakage current generated by the internal short circuit will change the changing rate of the voltage of the battery, by comparing the first changing rate of the voltage of the battery under test with the first target changing rate of the normal battery, it may be determined whether the internal short circuit occurs in the battery under test.

As disclosed, by comparing the first changing rate with the first target changing rate of the normal battery in the target scenario corresponding to the standard database, whether the internal short circuit occurs in the battery under test may be determined more timely, accurately, efficiently and conveniently.

In some embodiments, the method may further include:

S1001: determining a plurality of preset scenarios;

S1002: determining a second loading parameter of a second pulse current for each preset scenario of the plurality of preset scenarios;

S1003: determining a first target changing rate of the voltage of the normal battery by loading the second pulse current to the normal battery based on the second loading parameter, where the normal battery is a battery without an internal short circuit; and

S1004: loading the second pulse current on a plurality of short-circuited batteries based on the second loading parameter, to obtain a second target changing rate of the voltage of each of the plurality of short-circuited batteries.

One of the plurality of short-circuited batteries may be a battery with an internal short circuit and different short-circuited batteries may have different short circuit resistances.

A preset scenario where a normal battery or a short-circuited battery is located may be related to at least one of: the state of charge of the normal battery or the short-circuited battery; the charging/discharging rate of the normal battery or the short-circuited battery, or the temperature of the normal battery or the short-circuited battery.

To better understand the impact of different short circuit conditions on the battery, the internal short circuit behavior of the battery may be simulated in the form of a shunt resistor on the battery terminal, and the short circuit resistance of the short-circuited battery or the magnitude of the changing rate of the voltage may be used to quantify the degree of short circuit of the short-circuited battery.

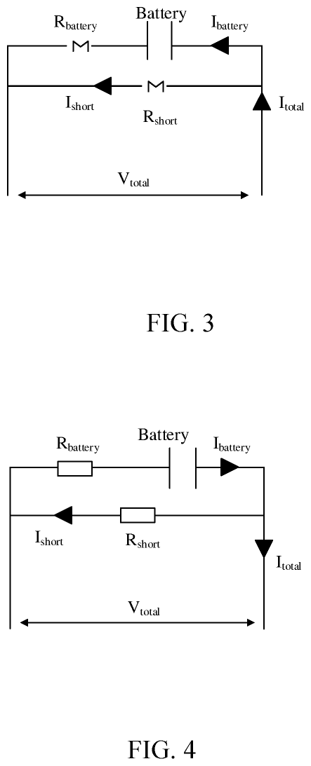

From the equivalent circuit of the charging state shown in FIG. 3, following equations may be obtained:

Iₜₒₜₐₗ=I_{battery}+Iₛₕₒᵣₜ (1);

Vₜₒₜₐₗ=V_{OCV}+R_{battery}×I_{battery}=Rₛₕₒᵣₜ×Iₛₕₒᵣₜ (2);

where Iₜₒₜₐₗ indicates the pulse current loaded on the short-circuited battery during the charging phase, Iₛₕₒᵣₜ indicates the short-circuit current, also known as the leakage current, I_{battery} indicates the current flowing to the short-circuited battery, V_{OCV} indicates the terminal voltage of the short-circuited battery in an open circuit state, R_{battery} indicates the internal resistance oft the short-circuited battery, Rₛₕₒᵣₜ indicates the resistance of the shunt at the simulated short circuit point, and Vₜₒₜₐₗ indicates the voltage of the short-circuited battery.

Combining (1) and (2) to remove Iₛₕₒᵣₜ, it may be derived that:

$${V}_{total} = \frac{{R}_{short}}{{R}_{battery} + {R}_{short}} \times {V}_{OCV} + \frac{{R}_{battery} \times {R}_{short}}{{R}_{battery} + {R}_{short}} \times {I}_{total} . \qquad ( 3 )$$

And the voltage Vₜₒₜₐₗ₋ₙₒᵣₘₐₗ of the normal battery may be represented as:

Vₜₒₜₐₗ₋ₙₒᵣₘₐₗ=V_{OCV}+R_{battery}×Iₜₒₜₐₗ (4)

Comparing (3) with (4) to subtract, the voltage difference ΔV₁ between the short-circuited battery and the normal battery under the condition of charging current may be obtained as:

$$Δ {V}_{1} = {V}_{total - normal} - {V}_{total} = \frac{{R}_{battery}}{{R}_{battery} + {R}_{short}} \times {V}_{OCV} + \frac{{{R}_{battery}}^{2}}{{R}_{battery} + {R}_{short}} \times {I}_{total} . \qquad ( 5 )$$

It can be seen from (5) that, when the loading current Iₜₒₜₐₗ is larger, the voltage difference ΔV₁ between the short-circuited battery and the normal battery may be larger. That is, the pulse current may have the effect of amplifying the leakage charge reaction. Further, the voltage difference may be larger when the detection is performed when it is close to full charge (that is, the state of charge is close to 100%, and when V_{OCV} is larger).

Further, it can be seen from (5) that, when the same pulse current is applied, the voltage Vₜₒₜₐₗ of the short-circuited battery may be lower than the voltage Vₜₒₜₐₗ of the normal battery.

Assuming that the internal resistance of the battery itself is 50 milliohms (mΩ) and the battery is charged with a charging current Iₜₒₜₐₗ of 8 amps (A) when the open circuit voltage V_{OCV} is 3.8V, the battery voltage Vₜₒₜₐₗ may be detected after a period of time Δt. That is, V_{OCV}=3.8V, Iₜₒₜₐₗ=8 A, R_{battery}=50 mΩ.

For the normal battery, Rₛₕₒᵣₜ→∞, Vₜₒₜₐₗ₋ₙₒᵣₘₐₗ=V_{OCV}+R_{battery}×Iₜₒₜₐₗ=3.8+0.05×8=4.2V. For the short-circuited battery, Rₛₕₒᵣₜ=20Ω,

$${V}_{total} = \frac{20}{20 + 0.05} \times 3.8 + \frac{0.05 \times 20}{20 + 0.05} \times 8 V = 4.1895 V .$$

That is, when the same pulse current is applied, the voltage of the short-circuited battery may be lower than the voltage of the normal battery.

When the battery has an internal short circuit, because of the existence of leakage current, the total power supply not only needs to charge the battery, but also a part of the current is distributed to the short circuit to generate heat when the same pulse current is applied during the charging phase. This may make the voltage increase (that is, the changing rate of voltage) smaller in a unit time.

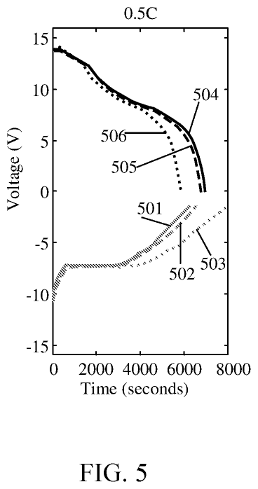

As shown in FIG. 5, in a certain preset scenario, the second pulse current loaded may be 0.5 C. In the charging stage, the solid line 501 represents the voltage curve of the normal battery, and the dotted lines 502 and 503 represent the voltage curves of the short-circuited battery of different short-circuit resistances. In the voltage curve of the normal battery, the internal resistance tends to be positive infinity, which may be expressed as Rₛₕₒᵣₜ→∞. The short-circuit resistance of the battery with short-circuit corresponding to the dotted line 503 may be smaller than the short-circuit resistance of the battery with short-circuit corresponding to the dotted line 502.

In the charging stage, the voltage of the battery with short-circuit may be lower than the voltage of the normal battery. That is, the voltage curve of the battery with short-circuit may be below the voltage curve of the normal battery. When the slope of the voltage curve is smaller, the voltage of the battery with short-circuit may be smaller. That is, when the voltage curve is lower, the slope of the voltage curve may be smaller. The degree of short circuit of the battery with short-circuit corresponding to the dotted line 503 may be more severe than the degree of short circuit of the battery with short-circuit corresponding to the dotted line 502.

From the equivalent circuit of the discharging state shown in FIG. 4, it may be obtained that:

I_{battery}=Iₜₒₜₐₗ+Iₛₕₒᵣₜ (6);

Vₜₒₜₐₗ=V_{OCV}+R_{battery}×I_{battery}=Rₛₕₒᵣₜ×Iₛₕₒᵣₜ (7).

Combining (6) and (7) to remove Iₛₕₒᵣₜ, it may be obtained that:

$${V}_{total} = \frac{{R}_{short}}{{R}_{short} - {R}_{battery}} \times {V}_{OCV} + \frac{{R}_{battery} \times {R}_{short}}{{R}_{short} - {R}_{battery}} \times {I}_{total} . \qquad ( 8 )$$

For the normal battery, Rₛₕₒᵣₜ→∞. Therefore,

Vₜₒₜₐₗ₋ₙₒᵣₘₐₗ=V_{OCV}+R_{battery}×Iₜₒₜₐₗ (9).

Comparing (8) with (9) to subtract, the voltage difference ΔV₂ between the short-circuited battery and the normal battery under the condition of charging current may be obtained as:

$$Δ {V}_{2} = {V}_{total - normal} - {V}_{total} -= \frac{{R}_{battery}}{{R}_{short} - {R}_{battery}} \times {V}_{OCV} + \frac{{{R}_{battery}}^{2}}{{R}_{short} - {R}_{battery}} \times {I}_{total} . \qquad ( 10 )$$

It can be seen from (10) that, when the loading current Iₜₒₜₐₗ is larger, the voltage difference ΔV₂ between the short-circuited battery and the normal battery may be larger. That is, the pulse current may have the effect of amplifying the leakage charge reaction, similar to the charging state.

Further, it can be seen from (10) that, when the internal short circuit occurs, the voltage Vₜₒₜₐₗ of the short-circuited battery may be lower than the voltage Vₜₒₜₐₗ₋ₙₒᵣₘₐₗ of the normal battery.

When the battery has an internal short circuit, because of the existence of leakage current, in the discharging stage, in addition to supplying Iₜₒₜₐₗ to the load, a part Iₛₕₒᵣₜ of the current may be dissipated at the short circuit to generate heat. The appearance may be that more charges are required, the voltage drops faster, and the changing rate of the voltage is larger (that is, the slope is steeper).

As shown in FIG. 5, in the discharging stage, the solid line 504 represents the voltage curve of the normal battery, and the dotted lines 505 and 506 represent the voltage curves of the short-circuited battery of different short circuit resistances. In the voltage curve of the normal battery, the internal resistance tends to be positive infinity, which may be expressed as Rₛₕₒᵣₜ→∞. The short-circuit resistance of the battery with short-circuit corresponding to the dotted line 506 may be smaller than the short-circuit resistance of the battery with short-circuit corresponding to the dotted line 505.

In the discharging stage, the voltage of the battery with short-circuit may be lower than the voltage of the normal battery. That is, the voltage curve of the battery with short-circuit may be below the voltage curve of the normal battery. When the degree of short circuit is more severe, the voltage of the battery with short-circuit may be smaller. That is, when the voltage curve is lower, the slope of the voltage curve may be larger. The degree of short circuit of the battery with short-circuit corresponding to the dotted line 506 may be more severe than the degree of short circuit of the battery with short-circuit corresponding to the dotted line 505.

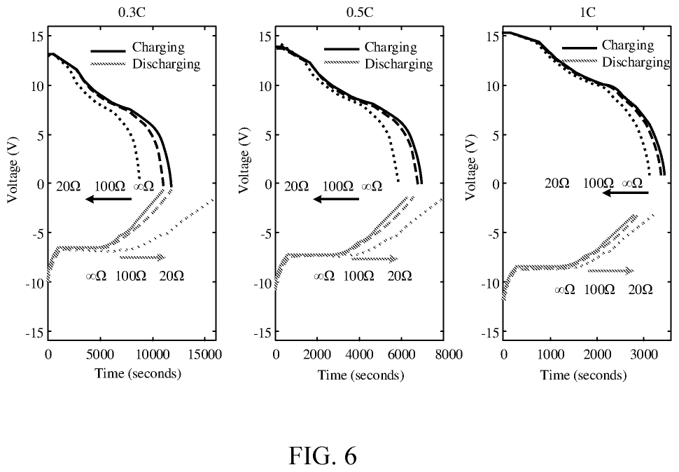

When the same pulse current is applied to the normal battery and the short-circuited battery during the charging phase or the discharging phase, the short-circuit resistance of the normal battery and the short-circuited battery may be different, and the changing rate of the voltage may be different. In different preset scenarios composed of different states of charge, different temperature, or different charging/discharging rates, the first target changing rate of the voltage of the normal battery under different second loading parameters corresponding to different preset scenarios, and the second target changing rate of the voltage of the short-circuited battery under different second loading parameters corresponding to different preset scenarios with different short-circuit resistances may be determined, such that a database capable of detecting early internal short-circuit resistances may be obtained. As shown in FIGS. 6, 601, 602 and 603 may be three different preset scenarios, and the second loading parameter may include current intensity and current loading time. Each preset scenario may correspond to a different current intensity and a different current loading time. The current intensity corresponding to the three preset scenarios may be 0.3 C, 0.5 C, and 1 C respectively, and the current loading time corresponding to the three preset scenarios may be 0 to 15000 seconds, 0 to 8000 seconds and 0 to 3000 seconds respectively. The different preset scenarios may correspond to different first target changing rates of voltage of the normal battery and different second changing rates of voltage of the short-circuited battery with different short-circuit resistances.

When the user is using the battery under test normally, he may regularly perform pulse current detection on the battery under test, and compare the actually detected first changing rate of the battery under test with the first target changing rate corresponding to the target scenario to determine whether the battery under test has a hidden failure risk (such as the soft short circuit).

As disclosed, by pre-determining the second loading parameters in different preset scenarios, the second pulse current of the second loading parameter may be applied to the normal battery and the short-circuited battery of different short-circuit resistances respectively, such that the actual detection result of the battery under test may be compared with the first target changing rate of the target scenario corresponding to the first scenario. It may be more timely, accurate and efficient to determine whether a soft short circuit occurs in the battery under test, and the short circuit degree of the soft short circuit, to prompt the user early. Potential safety hazards may be eliminated, improving the quality of portable terminal products.

In some embodiments, the first target changing rate corresponding to the target scenario may include the first target charging changing rate corresponding to the charging state and the first target discharging changing rate corresponding to the discharging state. In S1062, comparing the first changing rate with the first target changing rate corresponding to the target scenario to determine whether the internal short circuit occurs in the battery under test may include S10621 or S10622.

In S10621: when the first changing rate is less than the first target charging changing rate, it may be determined that the internal short circuit occurs in the battery under test.

As shown in FIG. 5, in the charging state, when the short-circuit situation is more severe, the voltage curve may be gentler. By comparing the first changing rate with the first target charging changing rate of the normal battery in the target scenario, when the first changing rate is less than the first target charging changing rate, it may be determined that the internal short circuit occurs in the battery under test. When the first changing rate is larger than or equal to the first target charging changing rate, it may be determined that the internal short circuit does not occur in the battery under test.

In S1062, when the first changing rate is larger than the first target discharging changing rate, it may be determined that the internal short circuit occurs in the battery under test.

As shown in FIG. 5, in the discharging state, when the short-circuit situation is more severe, the voltage curve may be steeper. By comparing the first changing rate with the first target discharging changing rate of the normal battery in the target scenario, when the first changing rate is larger than the first target discharging changing rate, it may be determined that the internal short circuit occurs in the battery under test. When the first changing rate is lesser than or equal to the first target discharging changing rate, it may be determined that the internal short circuit does not occur in the battery under test.

As disclosed, since the changing rate of the voltage of the short-circuited battery and the normal battery in the charging state or in the discharging state may have different variation trends with the degree of short circuit, the first changing rate may be compared with the first target charging changing rate of the normal battery in the target scenario in the charging state, and the first changing rate may be compared with the first target discharging changing rate of the normal battery in the target scenario in the discharging state. Therefore, it may be more timely, accurate and efficient to determine whether a soft short circuit occurs in the battery under test.

In some embodiments, the first scenario may be related to the state of charge of the battery under test. The method may further include:

S1031: in the charging state, determining to load the current when the state of charge of the battery under test is larger than a first threshold; and

S1032: in the discharging state, determining to load the current when the state of charge of the battery under test is smaller than a second threshold, where the second threshold is smaller than the first threshold.

The first threshold may be between 90% and 100%. As shown in FIG. 5, in the charging state, when the state of charge is larger, the difference of the changing rate between the normal battery and the short-circuited battery may be more obvious.

The second threshold may be between 0% and 10%. As shown in FIG. 5, in the discharge state, when the state of charge is smaller, the difference of the changing rate between the normal battery and the short-circuited battery may be more obvious.

As disclosed, since the difference of the changing rate between the normal battery and the short-circuited battery may be more obvious when the state of charge is larger in the charging state and the difference of the changing rate between the normal battery and the short-circuited battery may be more obvious when the state of charge is smaller in the discharging state, the first pulse current may be loaded when the state of charge is relatively larger in the charging state, or the first pulse current may be loaded when the state of charge is relatively small in the discharging state. Therefore, it may be more timely, accurate and efficient to determine whether a soft short circuit occurs in the battery under test.

In some embodiments, when it is determined that the internal short circuit occurs in the battery under test, the method may further include: reducing the working voltage range and reducing the current intensity; reminding the user on the user interface that the battery under test is abnormal; and increase the frequency of loading the first pulse current on the battery under test (that is, increase the detection frequency of the battery under test).

As disclosed, by reducing voltage and limiting current, reminding users, increasing detection frequency, etc., early detection of internal short circuits may be carried out to realize warning to users to avoid catastrophic events.

In some embodiments, the first scenario may be related to the temperature of the battery under test. The method may further include:

S108: when it is determined that the internal short circuit occurs in the battery under test, determining a corresponding short circuit resistance according to the first changing rate;

S110: obtaining a resistance threshold under the temperature corresponding to the first scenario; and

S112: when the short circuit resistance is smaller than the resistance threshold, preventing charging or discharging the battery under test.

The target scenario may correspond to a plurality of short-circuited batteries with different short-circuit resistances, and the second changing rates of each short-circuited battery may be different. The second target changing rate corresponding to the first changing rate may be determined, and the similarity between the second target changing rate and the first changing rate may be determined whether it is larger than the present threshold. As shown in FIG. 5, since different short circuit resistances correspond to different second target changing rate, the short circuit resistance of the second target changing rate corresponding to the first changing rate may be determined as the short circuit resistance of the first changing rate, that is, as the short circuit resistance of the battery under test.

The resistance threshold may be a charge prohibition resistance value in the charging state or a discharge prohibition resistance value in the discharging state. The charge prohibition resistance value and the discharge prohibition resistance value may be the same or different.

As disclosed, when the short circuit resistance is less than the resistance threshold, it may indicate that the short circuit degree of the battery under test is relatively serious at this time, and there may be a serious risk of hidden failure. The battery may be prevented from being charged or discharged, to avoid catastrophic events.

The present disclosure provides a method for diagnosing whether an internal short circuit occurs in a battery by using a pulse current probe. This method may detect the short circuit condition sensitively and accurately in the early stage (soft short circuit stage). By estimating the short circuit resistance and leakage charge level, the functions of informing the user of the true state of the battery and taking preventive measures in a timely manner may be realized.

As disclosed, the leakage current generated by the internal short circuit may occupy the charging/discharging capacity of the battery, and this leakage charge may accumulate throughout the charging/discharging cycle, making the aging battery in sharp contrast with the new-factory battery. When using the pulse current to push the leakage current to the limit, the influence of the leakage current may be amplified. By performing the pulse current limit test under different discharge/charge states of the battery, the resistance of the soft short circuit simulation circuit may be estimated to determine the condition of the internal short circuit of the battery.

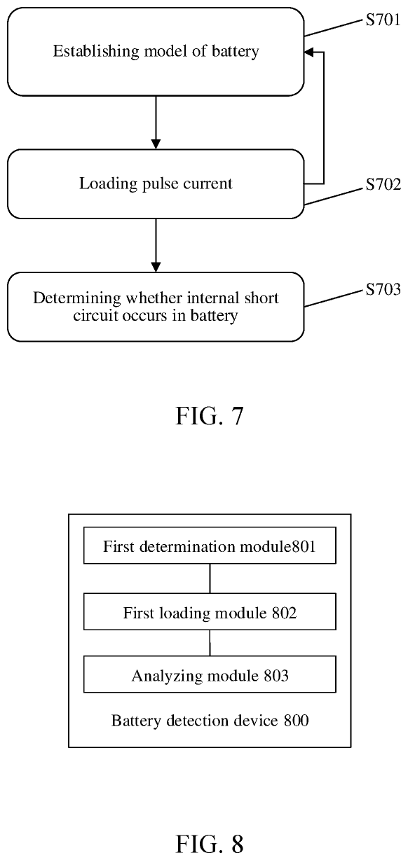

As shown in FIG. 7, the logical flow of the detection of the battery under test may include S701 to S703.

In S701, the battery model may be established.

The battery charging/discharging characteristic parameters, such as voltage, current, temperature, power and other information may be obtained, and the value of pulse loading current may be determined.

In S702, the pulsed current may be loaded.

The changing rate of the voltage over time of the normal batteries with different charging/discharging rates, different states of charge, or different temperatures may be obtained, and the changing rate of the voltage over time of batteries with different short-circuit resistances under corresponding conditions may be also obtained, to establish a database with different charging/discharging rates, different states of charge, or different temperatures. The battery charging/discharging characteristic parameters may be updated according to the data in the database.

In the actual application scenario, there may be batteries with different internal short-circuit degrees and aging degrees, that is, with different short-circuit resistance values. Also; the initial power state may be different, that is, the SOC may vary from 100% to 0%. During the charging test, the SOC may be set between 90% and 100%. During the discharging test, the SOC may be set between 0% and 10%. Therefore, the slope of the voltage curve of the normal battery and the short-circuit battery may have a larger difference. Under different temperature scenarios, the short-circuit resistance value may change, and the specified loading current may be different, which may be set to 0.1 C, 0.3 C, 0.5 C, 1 C, 2 C, etc. The specified loading current time may also be different, such as 1 s, 10 s, 1 min, etc. The specified cut-off voltage may also be different, such as 4.2V, 4.3V, 4.4V, etc. when charging, and 3.4V, 3.2V, 3.0V, etc. when discharging. The above permutations and combinations may form different preset scenarios and form a database.

In S703, it may be determined whether the internal short circuit happens in the battery.

By comparing the changing rate of the voltage of the battery under test over time with the changing rate of the voltage of the battery under normal conditions (that is, a normal battery) in the database over time, it may be determined whether the battery under test has an internal short circuit. When the internal short circuit occurs in the battery, the voltage reduction and current limiting process may be performed, and the user may be warned that the battery under test is abnormal.

As disclosed, when the above-mentioned battery detection method is realized in the form of a software function module and sold or used as an independent product, it may also be stored in a computer-readable storage medium. Based on this understanding, the essence of the technical solutions of the embodiments of the present disclosure or the parts that contribute to the related technologies may be embodied in the form of software products. The computer software products may be stored in a storage medium and include several instructions to make an electronic device (which may be a mobile phone, a tablet computer, a desktop computer, a personal digital assistant, a navigator, a digital phone, a video phone, a TV, a sensor device, etc.) execute all or part of the methods described in various embodiments of the present disclosure. The aforementioned storage medium may include a flash disk, a mobile hard disk, a read-only memory (ROM), a magnetic disk, an optical disk, or another medium capable of storing program codes. Thus, the scope of the present disclosure is not limited to any specific combination of hardware and software.

The present disclosure also provides a battery detection device. In one embodiment, as shown in FIG. 8, the battery detection device 800 may include a first determination module 801, a first loading module 802, and an analyzing module 803.

The first determination module 801 may be configured to determine a first loading parameter of a first pulse current.

The first loading module 802 may be configured to load the first pulse current on a battery under test based on the first loading parameter to obtain a first changing rate of the voltage of the battery under test.

The analyzing module 803 may be configured to determine whether an internal short circuit occurs in the battery under test based on the first changing rate.

In some embodiments, the device may further include: a second determination module configured to determine a first scenario of the battery under test; a third determination module configured to determine the first loading parameter of the first pulsed current based on the first scenario. The first scenario may be associated with at least one of the state of charge of the battery under test, the charging/discharging rate of the battery under test, or the temperature of the battery under test.

In some embodiments, the third determination module may include: a first determination sub-module configured to determine the current intensity of the first pulse current, the current loading time, the current intensity, or the cut-off voltage of the battery under test based on the first scenario. Correspondingly, the first loading module 802 may include a first obtaining sub-module configured to obtain the first changing rate of the voltage of the battery under test based on the current intensity and the current loading time, or a second obtaining sub-module configured to obtain the first changing rate of the voltage of the battery under test based on the current intensity and the cut-off voltage of the battery under test.

In some embodiments, the analyzing module 803 may include: a third determination sub-module, configured to determine a target scenario corresponding to the first scenario; and a comparison sub-module, configured to compare the first changing rate with a first target changing rate corresponding to the target scenario to determine whether an internal short circuit occurs in the battery under test. The target scenario may be a preset scenario in a standard database.

In some embodiments, the device may further include: a fourth determination module, configured to determine a plurality of different preset scenarios; a fifth determination module, configured to determine a second loading parameter of a second pulse current based on each preset scenario; a second loading module, configured to load the second pulse current on the normal battery based on the second loading parameter to obtain the first target changing rate of the voltage of the normal battery where the normal battery is a battery without internal short circuit; a third loading module, configured to apply the second pulse current to a plurality of different short-circuited batteries based on the second loading parameter to obtain a second target changing rate of the voltage of each short-circuited battery where one short-circuited battery is a battery with an internal short-circuit and different short-circuited batteries have different short-circuit resistances. The preset scenario where the normal battery or short-circuited battery is located may be associated with at least one of the state of charge of the normal battery or the short-circuited battery; the charging/discharging rate of the normal battery or the short-circuited battery; or the temperature of the normal battery or the short-circuited battery.

In some embodiments, the first target changing rate corresponding to the target scenario may include a first target charge changing rate corresponding to a charging state and a first target discharge changing rate corresponding to a discharging state. Correspondingly, the comparison sub-module may include: a first determination unit, configured to determine that an internal short circuit occurs in the battery under test when the first changing rate is less than the first target charge changing rate; or a second determination unit, configured to determine that an internal short circuit occurs in the battery under test when the first changing rate is larger than the first target discharge changing rate

In some embodiments, the first scenario may be associated with the state of charge of the battery under test. Correspondingly, the device may further include: a sixth determination module, configured to determine to load the current when the state of charge of the battery under test is larger than a first threshold in the charging state; and a seventh determination module, configured to determine to load the current when the state of charge of the battery under test is smaller than a second threshold in the discharging state. The first threshold may be larger than the second threshold.

In some embodiments, the first scenario may be associated with the temperature of the battery under test, and the device may further include: an eighth determination module, configured to determine the corresponding short-circuit resistance based on the first changing rate when it is determined that the internal short circuit occurs in the battery under test; an acquisition module configured to obtain the resistance threshold at the temperature corresponding to the first scenario; and a prohibition module configured to prohibit charging or discharging of the battery under test when the short-circuit resistance is less than the resistance threshold.

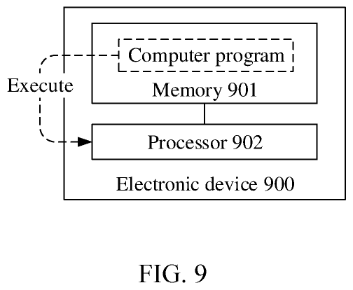

The present disclosure also provides an electronic device. As shown in FIG. 9, the device 900 may include a memory 901 and a processor 902. The memory 901 may be configured to store a computer program that can run on the processor 902. The processor 902 may be configured to execute the computer program to implement the battery detection method provided by various embodiments of the present disclosure.

The memory 901 may be configured to store instructions and applications executable by the processor 902, and may also store cache data to be processed or processed by the processor 902 or various modules in the device 900 (for example, image data, audio data, voice communication data, or video communication data). The memory may be realized by a flash memory (FLASH) or a random access memory (RAM).

The present disclosure also provides a computer-readable storage medium on which a computer program is stored. When the computer program is executed by a processor, t the battery detection method p provided by various embodiments of the present disclosure may be implemented.

As for the device and storage medium disclosed in the embodiments, since it corresponds to the method disclosed in the embodiments, the description is relatively simple, and for relevant details, the reference may be made to the description of the method embodiments.

As disclosed, the phrases such as “in one embodiment”, “in another embodiment”, “in yet another embodiment”, or “in other embodiments”, may all refer to one or more of different embodiments in accordance with the present disclosure. Each embodiment in this specification is described in a progressive manner, and each embodiment focuses on the difference from other embodiments. Same and similar parts of each embodiment may be referred to each other. Appearances of “in one embodiment” or “in the embodiment” in various places throughout the specification do not necessarily refer to the same embodiment. It should be understood that, in various embodiments of the present disclosure, the sequence numbers of the above-mentioned processes do not mean the order of execution and do not limit the scope of the present disclosure. The execution order of the processes should be determined by their functions and internal logic. The serial numbers of the above embodiments of the present disclosure are for description only, and do not represent the advantages and disadvantages of the embodiments.

The terms “comprises”, “includes”, or any other variation thereof are intended to cover a non-exclusive inclusion such that a process, method, article or apparatus comprising a set of elements includes not only those elements but also other elements not expressly listed elements, or also elements inherent in such a process, method, article, or device. Without further limitations, an element defined by the phrase “comprising a . . . ” does not preclude the presence of additional identical elements in the process, method, article, or apparatus comprising that element.

Devices and methods of the examples described in conjunction with the embodiments disclosed herein may be implemented by other manners. The device embodiments in the present disclosure are only schematic. For example, the division of the units is only a logical function division, and there may be other division methods in actual implementation. Multiple units or components can be combined, or can be integrated into another system, or some features can be ignored, or not implement. In addition, the coupling, or direct coupling, or communication connection between the components shown or discussed may be through some interfaces, and the indirect coupling or communication connection of devices or units may be electrical, mechanical or other forms of.

A unit described as a separate component may or may not be physically separated, and a component shown as a unit may or may not be a physical unit. It may be located in one place or distributed to multiple network units. Some or all of the units may be selected according to actual needs to achieve the purpose of the solution of the present disclosure. In addition, each functional unit in each embodiment of the present disclosure may be integrated into one processing unit, or each unit can be used as a single unit, or two or more units can be integrated into one unit. The above-mentioned integration unit can be realized in the form of hardware or in the form of hardware plus a software functional unit.

Devices and methods in the present disclosure may be realized by electronic hardware, computer software or a combination of the two. To clearly illustrate the possible interchangeability between the hardware and software, in the above description, the composition and steps of each example have been generally described according to their functions. Whether these functions are executed by hardware or software depends on the specific application and design constraints of the technical solution. Those skilled in the art may use different methods to implement the described functions for each specific application, but such implementation should not be regarded as exceeding the scope of the present disclosure.

Various modifications may be made to the embodiments of the present disclosure. Thus, the described embodiments should not be regarded as limiting, but are merely examples. Those skilled in the art will envision other modifications within the scope and spirit of the present disclosure. The accompanying drawings, which are incorporated in and constitute a part of this specification, illustrate embodiments of the present disclosure and, together with the general description of the present disclosure above and the detailed description of the embodiments below, serve to explain the principle of the present disclosure. These and other features of the present disclosure will become apparent from the following description of non-limiting embodiments with reference to the accompanying drawings. Although the present disclosure is described with reference to some specific examples, those skilled in the art will be able to realize many other equivalents of the present disclosure.

The above and other aspects, features, and advantages of the present disclosure will become more apparent in view of the following detailed description when taken in conjunction with the accompanying drawings. Specific embodiments of the present disclosure are hereinafter described with reference to the accompanying drawings. The described embodiments are merely examples of the present disclosure, which may be implemented in various ways. Specific structural and functional details described herein are not intended to limit, but merely serve as a basis for the claims and a representative basis for teaching one skilled in the art to variously employ the present disclosure in substantially any suitable detailed structure.

The steps of the methods or algorithms described in connection with the embodiments disclosed herein may be directly implemented by hardware, software modules executed by a processor, or a combination of both. Software modules may be placed in a random access memory (RAM), an internal memory, a read-only memory (ROM), an electrically programmable ROM, an electrically erasable programmable ROM, a register, a hard disk, a removable disk, a CD-ROM, or any other storage medium.

Part of all of the various embodiments provided by the present disclosure may be realized in the form of hardware related to program instructions, and the program may also be stored in a computer-readable storage medium. Based on this understanding, the essence of the technical solutions of the embodiments of the present disclosure or the parts that contribute to the related technologies may be embodied in the form of software products. The computer software products may be stored in a storage medium and include several instructions to make an electronic device (which may be a mobile phone, a tablet computer, a desktop computer, a personal digital assistant, a navigator, a digital phone, a video phone, a TV, a sensor device, etc.) execute all or part of the methods described in various embodiments of the present disclosure. The aforementioned storage medium may include a flash disk, a mobile hard disk, a read only memory (ROM), a magnetic disk, an optical disk, or another medium capable of storing program codes.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the present disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A battery detection method, comprising:
determining a first loading parameter of a first pulse current;
loading the first pulse current on a battery under test based on the first loading parameter to obtain a first changing rate of voltage of the battery under test; and
determining whether an internal short circuit occurs in the battery under test based on the first changing rate.

2. The method according to claim 1, further including:
determining a first scenario where the battery under test is located; and
determining the first loading parameter of the first pulse current based on the first scenario, wherein:
the first scenario is associated with at least one of: a state of charge of the battery under test, a charging/discharging rate of the battery under test, or temperature of the battery under test.

3. The method according to claim 2, wherein:
determining the first loading parameter of the first pulse current based on the first scenario includes determining a current intensity and a current loading time of the first pulse current, or determining the current intensity and cut-off voltage of the battery under test, according to the first scenario; and
loading the first pulse current on the battery under test based on the first loading parameter to obtain the first changing rate of voltage of the battery under test includes: obtaining the first changing rate of voltage of the battery under test according to the current intensity and the current loading time of the first pulse current; or obtaining the first changing rate of voltage of the battery under test according to the current intensity and the cut-off voltage of the battery under test.

4. The method according to claim 2, wherein determining whether the internal short circuit occurs in the battery under test based on the first changing rate includes:
determining a target scenario corresponding to the first scenario; and
comparing the first changing rate with a first target changing rate corresponding to the target scenario to determine whether the internal short circuit occurs in the battery under test, wherein the target scenario is a preset scenario in a standard database.

5. The method according to claim 4, further including:
determining a plurality of different preset scenarios;
determining a second loading parameter of a second pulse current based for each preset scenario of the plurality of preset scenarios;
loading the second pulse current on a normal battery based on the second loading parameter, to obtain a first target changing rate of the voltage of the normal battery, wherein the normal battery is a battery without the internal short circuit; and
loading the second pulse current on a plurality of different short-circuited batteries, to obtaining a second target changing rate of the voltage of each short-circuited battery of the plurality of short-circuited batteries, wherein one of the plurality of short-circuited batteries is a battery in which an internal short-circuit occurs and different short-circuited batteries of the plurality of short-circuited batteries have different short-circuit resistances.

6. The method according to claim 5, wherein:
one of the plurality of preset scenarios where the normal battery or the short-circuited battery is located is associated with at least one of the state of charge of the normal battery or the short-circuited battery, the charging/discharging rate of the normal battery or the short-circuited battery, or the temperature of the normal battery or the short-circuited battery.

7. The method according to claim 4, wherein:
the first target changing rate corresponding to the target scenario includes a first target charge changing rate corresponding to a charging state and a first target discharge changing rate corresponding to a discharging state; and
comparing the first changing rate with the first target changing rate corresponding to the target scenario to determine whether the internal short circuit occurs in the battery under test includes: determining that the internal short circuit occurs in the battery under test when the first changing rate is smaller than the first target charge changing rate; or determining that the internal short circuit occurs in the battery under test when the first changing rate is larger than the first target discharge changing rate.

8. The method according to claim 2, wherein the first scenario is related to the state of charge of the battery under test, the method further including:
in the charging state, determining to load the current when it is determined that the state of charge of the battery under test is larger than a first threshold; and
in the discharging state, determining to load the current when it is determined that the state of charge of the battery under test is smaller than a second threshold, wherein the first threshold is larger than the second threshold.

9. The method according to claim 2, wherein the first scenario is related to the temperature of the battery under test, the method further including:
when it is determined that the internal short circuit occurs in the battery under test, determining the corresponding short-circuit resistance based on the first changing rate;
obtaining a resistance threshold at the temperature corresponding to the first scenario; and
when the short-circuit resistance is smaller than the resistance threshold, prohibiting the charging or discharging of the battery under test.

10. An electronic device, comprising:
one or more processors; and
a memory coupled to the one or more processors and storing computer program instructions that, when being executed, cause the one or more processors to perform:
determining a first loading parameter of a first pulse current;
loading the first pulse current on a battery under test based on the first loading parameter to obtain a first changing rate of voltage of the battery under test; and
determining whether an internal short circuit occurs in the battery under test based on the first changing rate.

11. The electronic device according to claim 10, wherein the one or more processors are further configured to perform:
determining a first scenario where the battery under test is located; and
determining the first loading parameter of the first pulse current based on the first scenario, wherein:
the first scenario is associated with at least one of a state of charge of the battery under test, a charging/discharging rate of the battery under test, or temperature of the battery under test.

12. The electronic device according to claim 11, wherein the one or more processors are further configured to perform:
determining a current intensity and a current loading time of the first pulse current, or determining the current intensity and cut-off voltage of the battery under test, according to the first scenario; and
obtaining the first changing rate of voltage of the battery under test according to the current intensity and the current loading time of the first pulse current; or obtaining the first changing rate of voltage of the battery under test according to the current intensity and the cut-off voltage of the battery under test.

13. The electronic device according to claim 11, wherein the one or more processors are further configured to perform:
determining a target scenario corresponding to the first scenario; and
comparing the first changing rate with a first target changing rate corresponding to the target scenario to determine whether the internal short circuit occurs in the battery under test, wherein the target scenario is a preset scenario in a standard database.

14. The electronic device according to claim 13, wherein the one or more processors are further configured to perform:
determining a plurality of different preset scenarios;
determining a second loading parameter of a second pulse current based for each preset scenario of the plurality of preset scenarios;
loading the second pulse current on a normal battery based on the second loading parameter, to obtain a first target changing rate of the voltage of the normal battery, wherein the normal battery is a battery without the internal short circuit; and
loading the second pulse current on a plurality of different short-circuited batteries, to obtaining a second target changing rate of the voltage of each short-circuited battery of the plurality of short-circuited batteries, wherein one of the plurality of short-circuited batteries is a battery in which an internal short-circuit occurs and different short-circuited batteries of the plurality of short-circuited batteries have different short-circuit resistances.

15. The electronic device according to claim 14, wherein:
one of the plurality of preset scenarios where the normal battery or the short-circuited battery is located is associated with at least one of the state of charge of the normal battery or the short-circuited battery, the charging/discharging rate of the normal battery or the short-circuited battery, or the temperature of the normal battery or the short-circuited battery.

16. The electronic device according to claim 13, wherein:
the first target changing rate corresponding to the target scenario includes a first target charge changing rate corresponding to a charging state and a first target discharge changing rate corresponding to a discharging state; and
the one or more processors are further configured to perform: determining that the internal short circuit occurs in the battery under test when the first changing rate is smaller than the first target charge changing rate; or determining that the internal short circuit occurs in the battery under test when the first changing rate is larger than the first target discharge changing rate.

17. The electronic device according to claim 10, wherein the first scenario is related to a state of charge of the battery under test, wherein the one or more processors are further configured to perform:
in the charging state, determining to load the current when it is determined that the state of charge of the battery under test is larger than a first threshold; and
in the discharging state, determining to load the current when it is determined that the state of charge of the battery under test is smaller than a second threshold, wherein the first threshold is larger than the second threshold.

18. The electronic device according to claim 10, wherein the first scenario is related to the temperature of the battery under test, and the one or more processors are further configured to perform:
when it is determined that the internal short circuit occurs in the battery under test, determining the corresponding short-circuit resistance based on the first changing rate;
obtaining a resistance threshold at the temperature corresponding to the first scenario; and
when the short-circuit resistance is smaller than the resistance threshold, prohibiting the charging or discharging of the battery under test.

19. A non-transitory computer readable storage medium containing computer program instructions that, when being executed, cause one or more processors to perform:
determining a first loading parameter of a first pulse current;
loading the first pulse current on a battery under test based on the first loading parameter to obtain a first changing rate of voltage of the battery under test; and
determining whether an internal short circuit occurs in the battery under test based on the first changing rate.

20. The storage medium according to claim 19, wherein the one or more processors are further configured to perform:
determining a first scenario where the battery under test is located; and
determining the first loading parameter of the first pulse current based on the first scenario, wherein:
the first scenario is associated with at least one of a state of charge of the battery under test, a charging/discharging rate of the battery under test, or temperature of the battery under test.
